(19) United States
(12) Patent Application Publication
(10) Pub. No.: US 2026/0059800 A1
(43) Pub. Date: Feb. 26, 2026

(54) FLUORINE INCORPORATION FOR GAA TRANSISTORS AND THE STRUCTURES THEREOF

(71) Applicant: Taiwan Semiconductor Manufacturing Co., Ltd., Hsinchu (TW)

(72) Inventors: Chung-Yi Su, Taipei City (TW); Pin-Hsuan Yeh, Taipei City (TW); Chin-You Hsu, Hsinchu (TW); Han-Lin Yang, Taichung City (TW); Kuan-Ting Liu, Hsinchu (TW); Hsien-Ming Lee, Changhua (TW); Chi On Chui, Hsinchu (TW)

(21) Appl. No.: 18/813,628

(22) Filed: Aug. 23, 2024

(51) Int. Cl. H01L 29/423; H01L 21/02; H01L 21/324; H01L 21/8234; H01L 27/088; H01L 29/06; H01L 29/66; H01L 29/775; H01L 29/786

(52) U.S. Cl. CPC H10D 30/6735; H01L 21/02205; H01L 21/0228; H01L 21/324; H10D 30/014; H10D 30/43; H10D 30/6757; H10D 62/121; H10D 64/017; H10D 84/0128; H10D 84/038; H10D 84/83

(57) ABSTRACT

A method includes removing a dummy gate stack to form a trench between gate spacers, and removing a sacrificial layer contacting a semiconductor region. The sacrificial layer and the semiconductor region are in the trench. The method further includes depositing a gate dielectric into the trench and on the semiconductor region, depositing a liner on the gate dielectric, depositing a fluorine-containing layer over the liner, performing a drive-in process to drive fluorine in the fluorine-containing layer into the gate dielectric, and depositing a conductive layer over the gate dielectric.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 18A and 18B illustrate the views of intermediate stages in the formation of nanostructure transistors in accordance with some embodiments.

FIG. 19 illustrates a schematic distribution profile of fluorine in accordance with some embodiments.

FIG. 20 illustrates a process flow for forming nanostructure transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors (also referred to as nanostructure transistors) and the method of incorporating fluorine into the gate dielectrics of the GAA transistors are provided. In accordance with some embodiments, semiconductor nanostructures, which form the channel regions of the GAA transistors, are formed. The sacrificial layers between the semiconductor nanostructures are removed. Liners are formed on the semiconductor nanostructures, followed by the deposition of a fluorine-containing layer. A drive-in process is then performed, and the fluorine-containing layer and the liners are removed. The profile of the liners is adjusted to suit to the profiles of the semiconductor nanostructures and to adjust the distribution of fluorine, so that the performance of the transistors may be adjusted.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

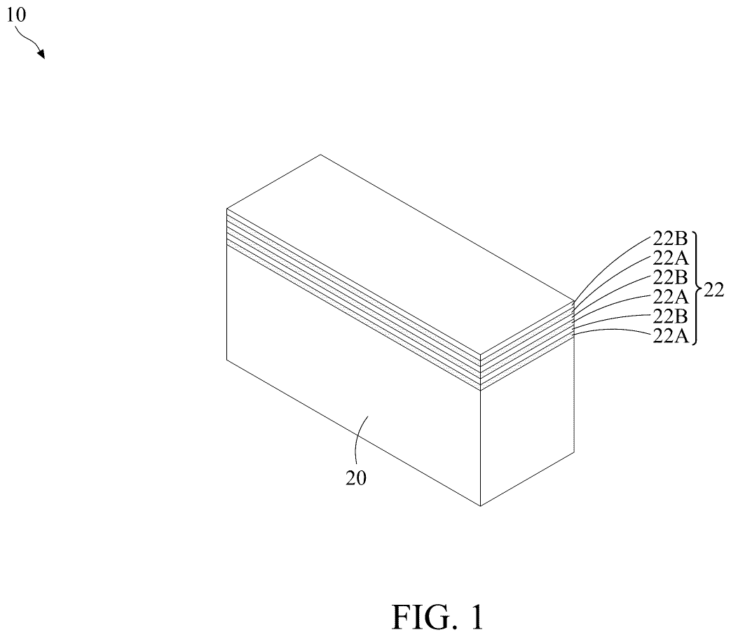

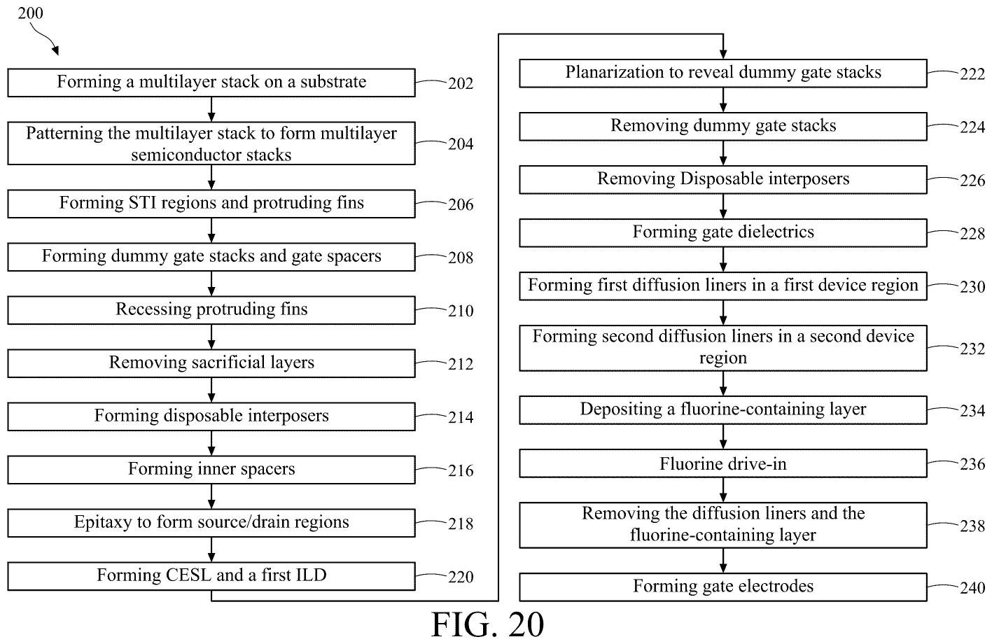

FIGS. 1 through 18A and 18B illustrate the cross-sectional views of intermediate stages in the formation of GAA transistors in accordance with some embodiments of the present disclosure. The corresponding processes are also reflected schematically in the process flow shown in FIG. 20.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 as shown in FIG. 20. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of the first layers 22A is formed of or comprises a semiconductor such as SiGe, Ge, Si, GaAs, InSb, GaSb, InAlAs, InGaAs, GaSbP, GaAsSb, or the like. The deposition of first layers 22A (for example, SiGe) may be through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layers 22A are formed to a first thickness in the range between about 30 Å and about 300 Å. However, any suitable thickness may be utilized while remaining within the scope of the embodiments.

In accordance with some embodiments, the second material of the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of the first layers 22A. For example, in accordance with some embodiments in which the first layers 22A are formed of silicon germanium, the second layers 22B may be formed of silicon, or vice versa.

In accordance with some embodiments, the first layers 22A have thicknesses the same as or similar to each other, and the second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

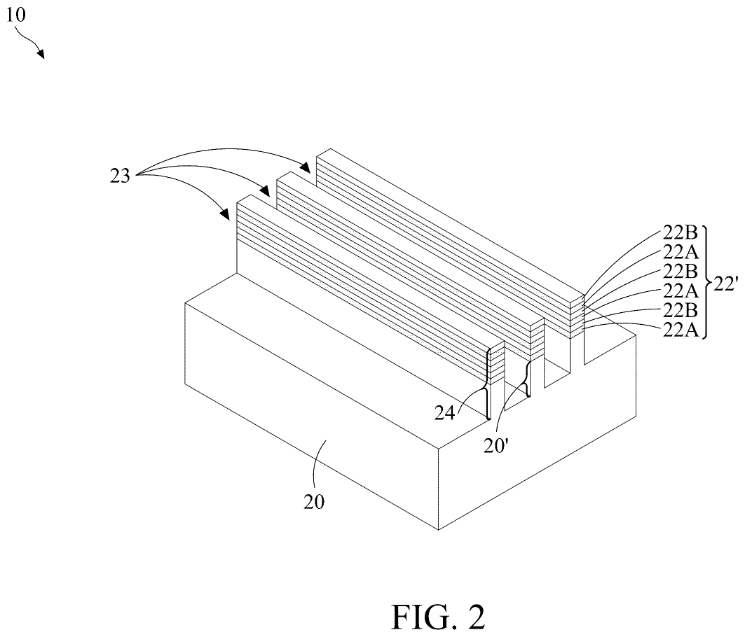

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 20. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

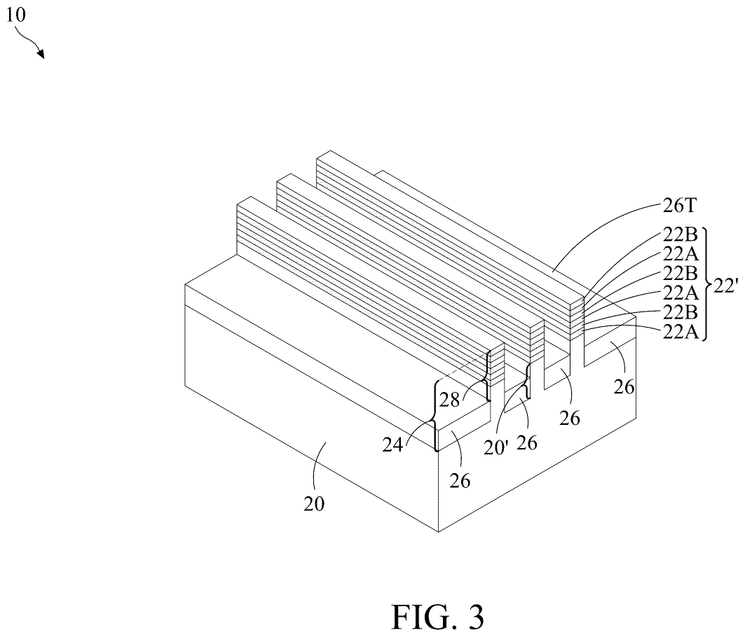

FIG. 3 illustrates the formation of isolation regions 26, which are also referred to as Shallow Trench Isolation (STI) regions throughout the description. The respective process is illustrated as process 206 in the process flow 200 as shown in FIG. 20. STI regions 26 may include a liner oxide (not shown), which may be a thermal oxide formed through the thermal oxidation of a surface layer of substrate 20, or may be deposited. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

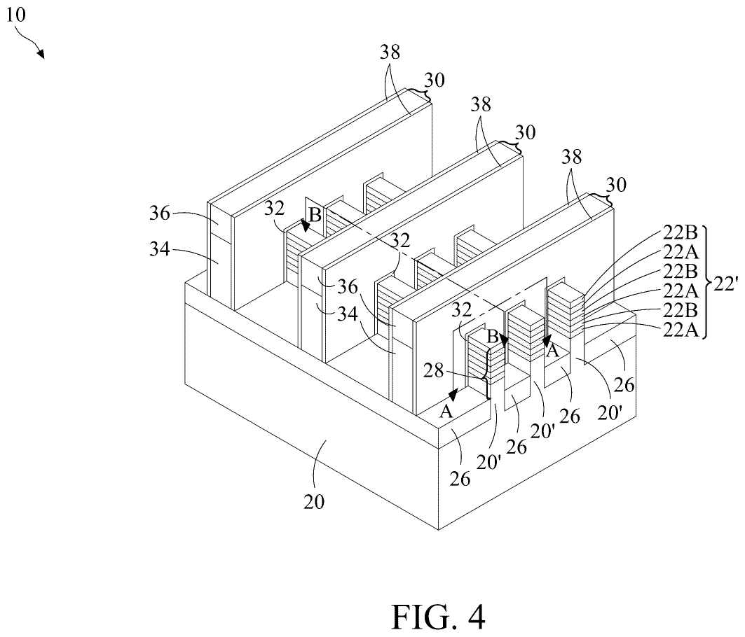

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 20. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

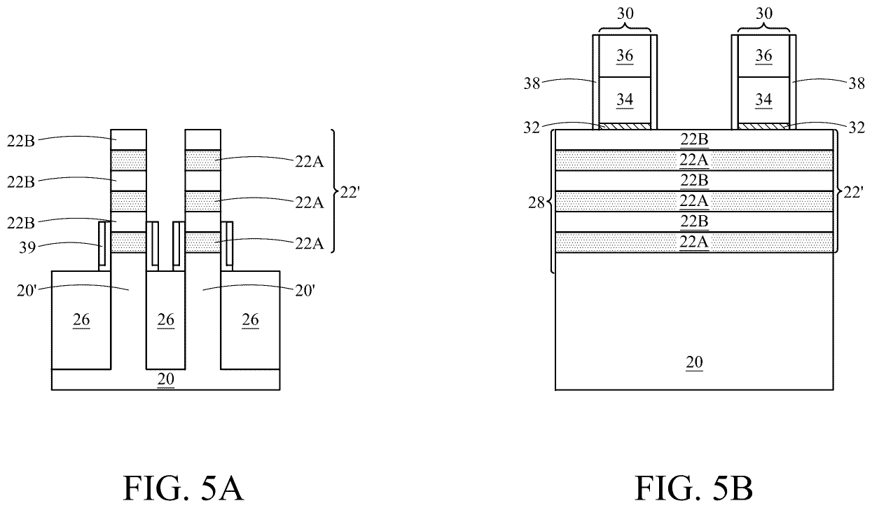

FIGS. 5A and 5B illustrate the cross-sectional views of the structure shown in FIG. 4. FIG. 5A illustrates the reference cross-section A-A in FIG. 4, which cross-section cuts through the portions of protruding fins 28 not covered by gate stacks 30 and gate spacers 38, and is perpendicular to the gate-length direction. Fin spacers 39, which are on the sidewalls of protruding fins 28, are also illustrated. FIG. 5B illustrates the reference cross-section B-B in FIG. 4, which reference cross-section is parallel to the lengthwise directions of protruding fins 28.

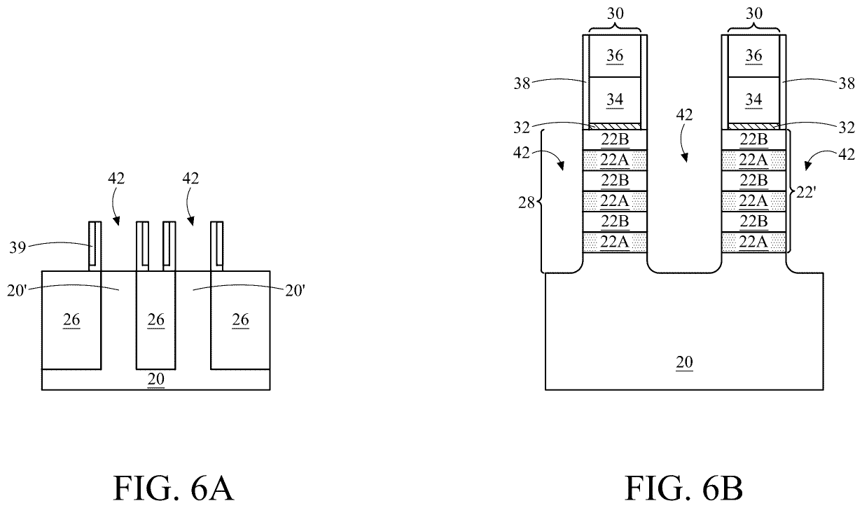

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 as shown in FIG. 20. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight.

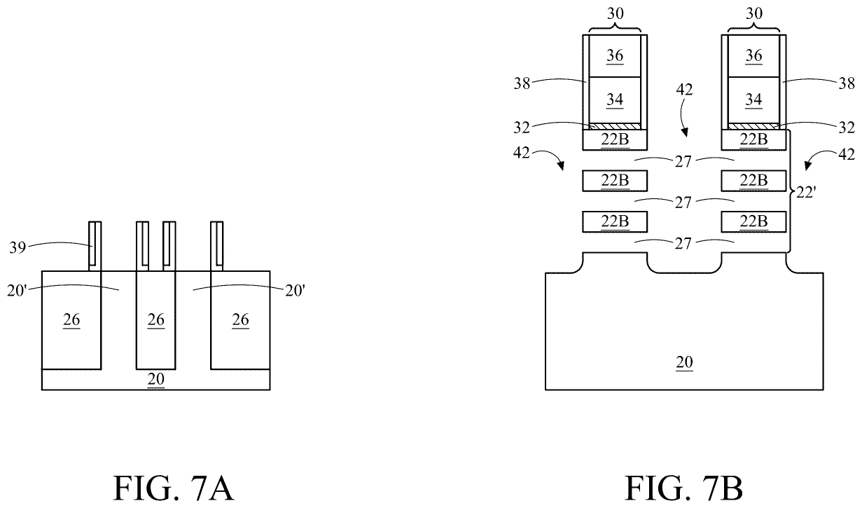

Next, referring to FIGS. 7A and 7B, the sacrificial layers 22A are removed through an etching process, so that spaces 27 are left between neighboring nanostructures 22B. The respective process is illustrated as process 212 in the process flow 200 as shown in FIG. 20. The etching may be performed using an isotropic etching process such as a wet etching process or a dry etching process.

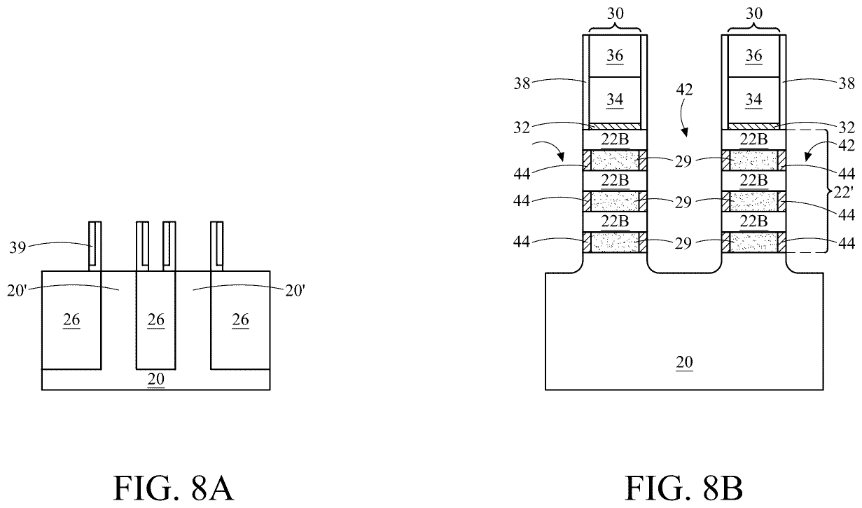

Referring to FIGS. 8A and 8B, Disposable interposers 29 are formed to fill the spaces 27 and separate nanostructures 22B from each other. The respective process is illustrated as process 214 in the process flow 200 as shown in FIG. 20. Disposable interposers 29 are also sacrificial layers that replace sacrificial layers 22A, and thus are alternatively referred to as (replacement) sacrificial layers 29. In accordance with some embodiments, disposable interposers 29 comprise an oxide such as silicon oxide, and thus may also be referred to as Disposable Oxide Interposers (DOIs) 29. In accordance with other embodiments, any other types of materials (such as SiON, Al₂O₃, or the like) that do not intermix with nanostructures 22B during the subsequent formation of source/drain regions may be adopted to form the disposable interposers 29.

The formation of disposable interposers 29 may include depositing a dielectric layer, for example, using a conformal deposition process. The deposited dielectric layer includes some portions filling the spaces between nanostructures 22B, and some other portions outside of the openings. An anisotropic etching process and/or an isotropic etching process is then performed to trim and remove the portions of the dielectric layer outside of the spaces. The remaining portions of the dielectric layer are thus the disposable interposers 29.

Further referring to FIGS. 8A and 8B, disposable interposers 29 are laterally recessed and filled to form inner spacers 44. The respective process is illustrated as process 216 in the process flow 200 as shown in FIG. 20. The lateral recessing of the disposable interposers 29 may be achieved through a wet etching process or a dry etching process. The wet etching process may be performed using a dip process, a spray process, a spin-on process, or the like. Nanostructures 22B are not etched.

Inner spacers 44 are then formed. In accordance with some embodiments, the formation of inner spacers 44 includes depositing a conformal dielectric layer, which extends into the lateral recesses. Next, an etching process (also referred to as a spacer trimming process) is performed to trim the portions of the spacer layer outside of the lateral recesses, leaving the portions of the spacer layer in the lateral recesses. The remaining portions of the spacer layer are referred to as inner spacers 44.

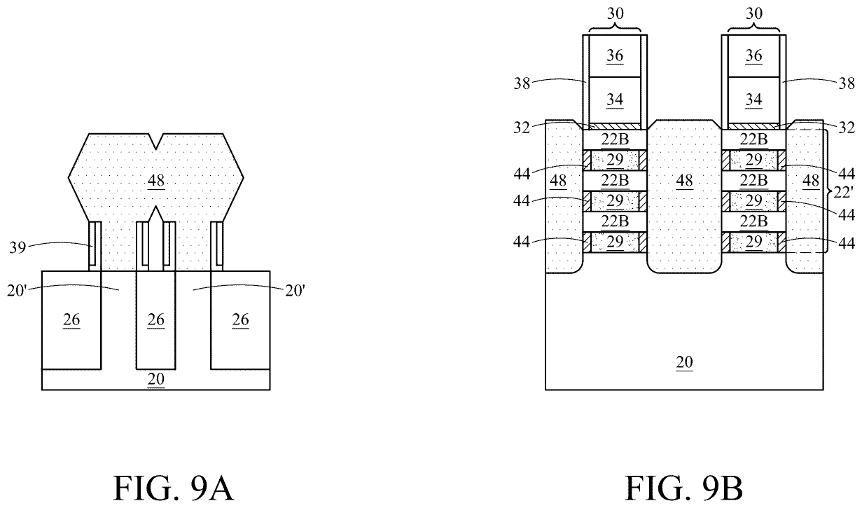

Referring to FIGS. 9A and 9B, epitaxial source/drain regions 48 are formed in recesses 42 through selective epitaxy. The respective process is illustrated as process 218 in the process flow 200 as shown in FIG. 20. Depending on whether the resulting transistor is a p-type transistor or an n-type transistor, a p-type or an n-type impurity may be in-situ doped with the proceeding of the epitaxy. For example, when the resulting transistor is a p-type transistor, silicon germanium boron (SiGeB), silicon boron (SiB), or the like may be grown. Conversely, when the resulting transistor is an n-type transistor, silicon phosphorous (SiP), silicon carbon phosphorous (SiCP), or the like may be grown.

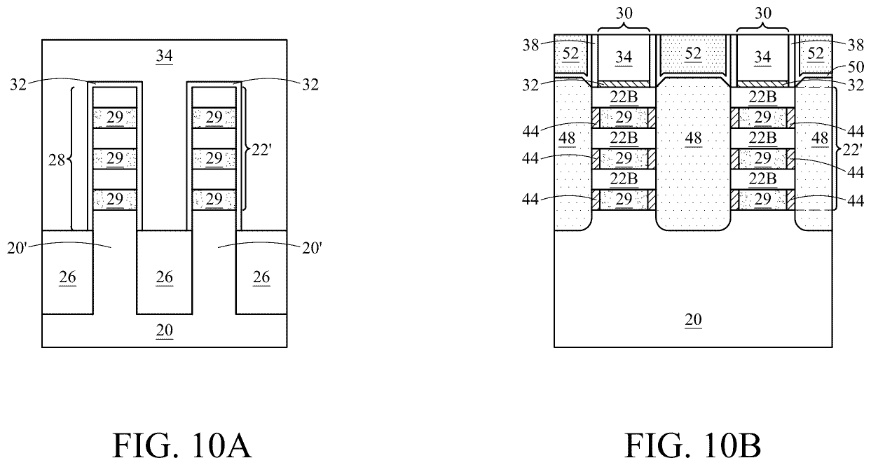

FIGS. 10A and 10B illustrate the cross-sectional views of the structure after the formation of Contact Etch Stop Layer (CESL) 50 and Inter-Layer Dielectric (ILD) 52. The respective process is illustrated as process 220 in the process flow 200 as shown in FIG. 20. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. The respective process is illustrated as process 222 in the process flow 200 as shown in FIG. 20. In accordance with some embodiments, the planarization process may remove hard masks 36 to reveal dummy gate electrodes 34, as shown in FIGS. 9A and 9B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

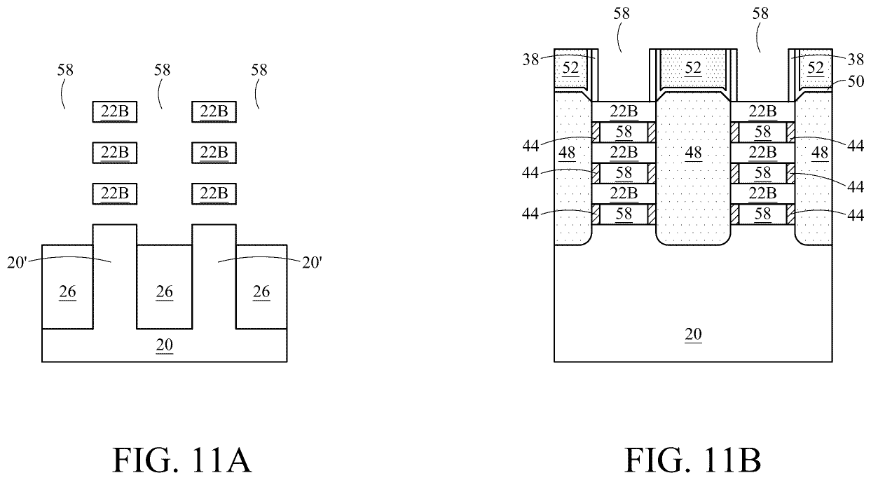

Next, dummy gate electrodes 34 and dummy gate dielectrics 32 (and hard masks 36, if remaining) are removed in one or more etching processes, so that recesses 58 are formed, as shown in FIGS. 11A and 11B. The respective process is illustrated as process 224 in the process flow 200 as shown in FIG. 20. In accordance with some embodiments, dummy gate electrodes 34 and dummy gate dielectrics 32 are removed through an anisotropic and/or isotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Disposable interposers 29 (sacrificial layers) are then removed to extend recesses 58 between nanostructures 22B. The respective process is illustrated as process 226 in the process flow 200 as shown in FIG. 20. Disposable interposers 29 may be removed by performing an isotropic etching process such as dry etching process or a wet etching process using an etchant that is selective to the materials of disposable interposers 29, while nanostructures 22B and substrate 20 remain relatively un-etched as compared to disposable interposers 29.

In accordance with some embodiments in which disposable interposers 29 are formed of silicon oxide (DOI), when dry etching is performed, the etching gases may include the mixture of NF₃ and NH₃, the mixture of HF and NH₃, or the like. When wet etching is performed, diluted HF may be used.

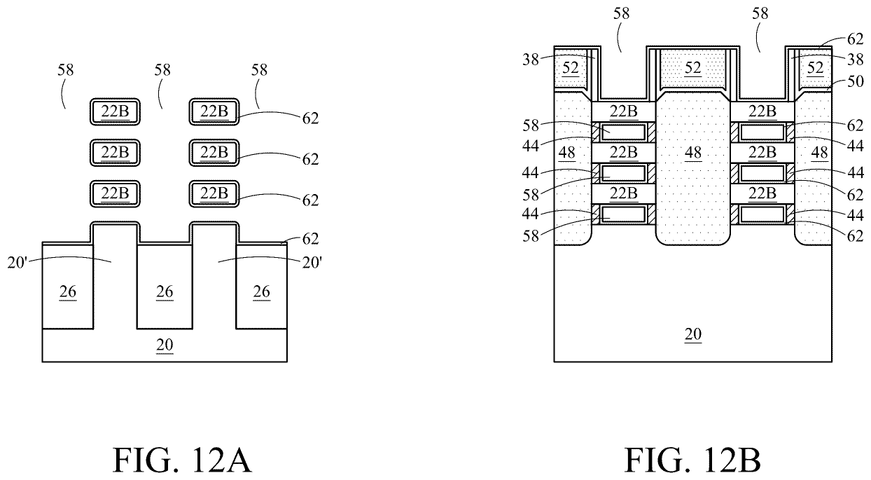

Referring to FIGS. 12A and 12B, gate dielectrics 62 are formed. The respective process is illustrated as process 228 in the process flow 200 as shown in FIG. 20. In accordance with some embodiments, each of gate dielectrics 62 includes an interfacial layer and a high-k dielectric layer over the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

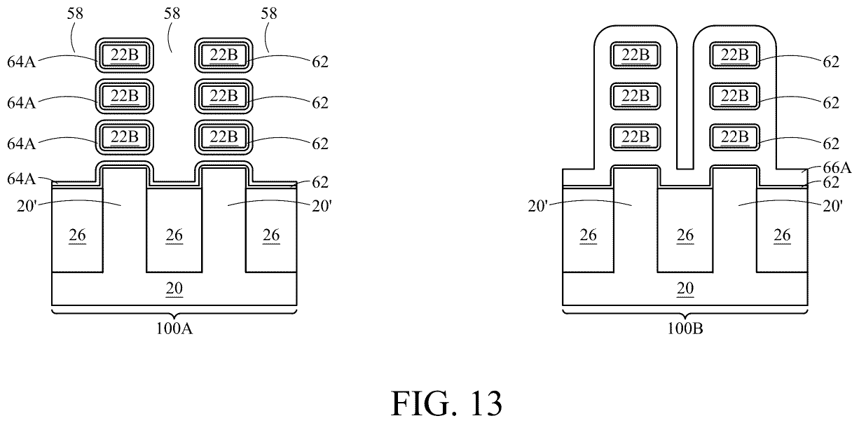

Next, a fluorine-incorporation process is performed, as shown in FIGS. 13 through 15. The fluorine-incorporation process is used to incorporate fluorine into the high-k dielectric layers, so that the high-k dielectric layers are passivated, and the defects in the high-k dielectric layers are repaired.

Referring to FIG. 13, diffusion liner 64A is deposited. The respective process is illustrated as process 230 in the process flow 200 as shown in FIG. 20. In accordance with some embodiments, the wafer and the device die include device regions 100A and 100B. The subsequent fluorine-incorporation processes are performed on the gate dielectrics in device regions 100A and 100B differently, as will be discussed in detail in subsequent paragraphs. Each of the device regions 100A and 100B may be used for forming a p-type transistor or an n-type transistor, and the conductivity type of the transistors in device regions 100A and 100B can be the same or opposite.

In accordance with some embodiments, diffusion liner 64A comprises a metal-containing material such as a metal compound (such as a metal nitride), an elemental metal layer (in which the metal is not in the form of a compound), a metal alloy, or the like. For example, diffusion liner 64A may comprise TiN, WN, WCN, Mo, MoN, Ti, TiAl, TiN, or the like.

In accordance with some embodiments, the diffusion liner 64A is formed using a conformal deposition process such as ALD, CVD, or the like. The process conditions, however, may be adjusted, so that while diffusion liner 64A encircle nanostructures 22B, the profile of diffusion liner 64A is adjusted, and the ratios of the thicknesses of different portions of diffusion liner 64A may be adjusted, as will be discussed in subsequent paragraphs. The process conditions for forming diffusion liner 64A may also be tuned so that different portions of diffusion liner 64A may have the same thickness.

In accordance with some embodiments, the diffusion liner 64A is formed in device region 100A, but is not formed in device region 100B. The formation process may include forming a patterned hard mask 66A (such as BN, SiN, or the like) in device region 100B, depositing diffusion liner 64A, and removing the hard mask 66A. The dielectric diffusion liner 64A deposited on the hard mask 66A is lifted along with the removal of the hard mask 66A. Alternatively, the diffusion liner 64A is deposited into both of device region 100A and 100B, followed by forming an etching mask (such as a photoresist) to cover device region 100A, and removing the portion of diffusion liner 64A from device region 100B. Hard mask 66A is then removed.

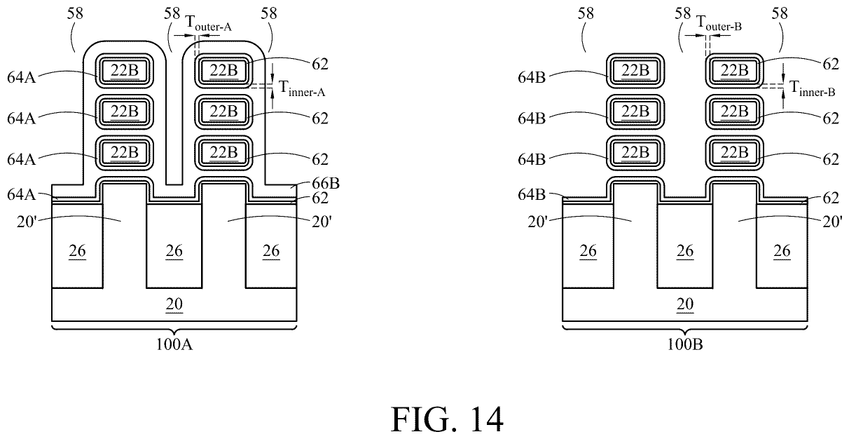

FIG. 14 illustrates the formation of diffusion liner 64B, which has a profile (including, for example, thickness ratios) different from the profile of diffusion liner 64A. The respective process is illustrated as process 232 in the process flow 200 as shown in FIG. 20. The material of diffusion liner 64B may be selected from the same group of candidate material for forming diffusion liner 64A, and may be the same or different from the material of diffusion liner 64A.

In accordance with some embodiments, the diffusion liner 64B is also formed using a conformal deposition process such as ALD, CVD, or the like. The process conditions, however, may be adjusted, so that while diffusion liner 64B encircles nanostructures 22B, different portions of diffusion liner 64B may have a slight difference, as will be discussed in subsequent paragraphs. The process conditions for forming diffusion liner 64B may also be tuned so that different portions of diffusion liner 64B may have the same thickness or different thicknesses.

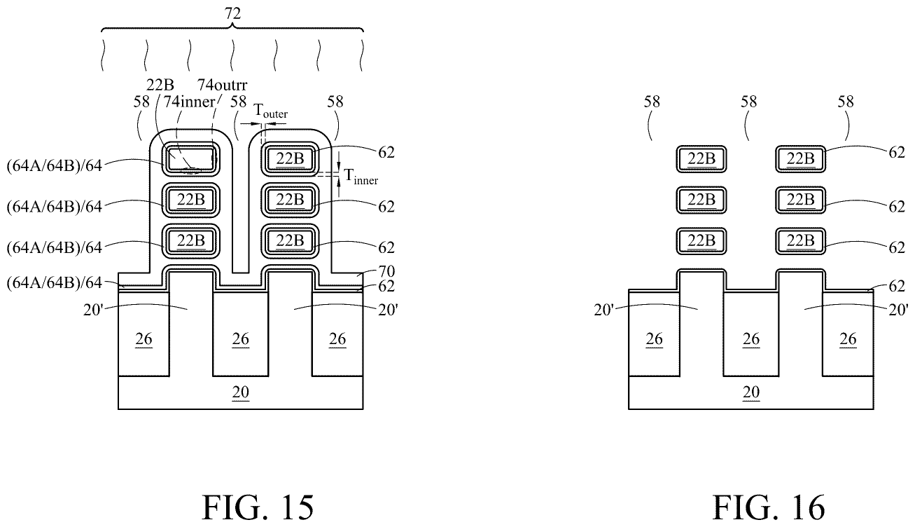

The process conditions for forming diffusion liner 64B may also be tuned, so that the profile of diffusion liner 64B is different from the profile of diffusion liner 64A. The details of the different profiles and the respective formation process conditions may be discussed referring to the discussion of the fluorine drive-in process as shown in FIG. 15.

In accordance with some embodiments, the diffusion liner 64B is formed in device region 100B, but is not formed in device region 100A. The formation process may include forming a patterned hard mask 66B in device region 100A, depositing diffusion liner 64B, and removing the hard mask 66B. The dielectric diffusion liner 64B deposited on the hard mask 66B is thus removed along with the removal of the hard mask 66B. Alternatively, the diffusion liner 64B is deposited into both of device region 100A and 100B, followed by forming an etching mask (such as a photoresist) to cover device region 100B, and removing the portion of diffusion liner 64B from device region 100A. In accordance with some embodiments, the diffusion liners 64A and 64B may have thicknesses in the range between about 0.5 nm and about 5 nm.

Referring to FIG. 15, fluorine-containing layer 70 is deposited. The respective process is illustrated as process 234 in the process flow 200 as shown in FIG. 20. In accordance with some embodiments, the fluorine-containing layer 70 is deposited using a fluorine-containing precursor such as tungsten hexafluoride (WF₆) or other applicable precursors. In accordance with some embodiments, the precursor further includes a reducing agent such as diborane (B₂H₆), hydrogen (H₂), a silicon-containing precursor such as silane, or combinations thereof. The formation may be performed through (thermal) ALD. The ALD process may include a plurality of cycles, each comprising pulsing the fluorine-containing tungsten precursor, purging the fluorine-containing tungsten precursor, pulsing the reducing agent, and purging the reducing agent.

Further referring to FIG. 15, a fluorine drive-in process 72 is performed, for example, through an annealing process. The respective process is illustrated as process 236 in the process flow 200 as shown in FIG. 20. The structure shown in FIG. 15 represents both of the structure in device region 100A and the structure in device region 100B. Accordingly, the liner is denoted as 64, which represents either one or both of diffusion liners 64A and 64B. The fluorine drive-in process 72 may be in-situ performed in the same environment (such as the vacuum chamber or the furnace) in which the fluorine-containing layer 70 is deposited. Alternatively, the fluorine drive-in process 72 may be ex-situ performed in a different environment than the environment in which fluorine-containing layer 70 is deposited. For example, the annealing process may be performed in another vacuum chamber or furnace. In accordance with some embodiments, the wafer temperature in the annealing process may be in the range between about 400° C. and about 650° C.

During the fluorine drive-in process 72, fluorine is driven from fluorine-containing layer 70 into (diffuse into) gate dielectrics 62, and possibly into nanostructures 22B. Tungsten is heavier and hence has a lower diffusion rate than fluorine. Accordingly, after the fluorine-containing layer 70, the tungsten remains in fluorine-containing layer 70.

In accordance with alternative embodiments, the fluorine, instead of being deposited as a separate layer on diffusion liners 64 and then driven in through a subsequent drive-in process 72, is incorporated into the diffusion liners 64 and gate dielectrics 62 through a soaking process. In the soaking process, the diffusion liners 64 and the gate dielectrics 62 are soaked in a fluorine-containing gas such as WF₆ (without providing reducing agent for depositing fluorine-containing layer 70), so that the fluorine may diffuse into gate dielectrics 62 directly. The soaking process may be performed when the respective wafer is heated.

In accordance with some embodiments in which the soaking process is performed to incorporate fluorine, there may be no fluorine-containing layer 70 formed. Alternatively, there may be a very thin fluorine-containing layer 70 formed, which is thin enough to be diffused into (and absorbed by) gate dielectrics 62 and the subsequently formed overlying layers such as gate electrodes. Accordingly, the etching process (process 238, FIG. 20) for removing the fluorine-containing layers 70 may be skipped.

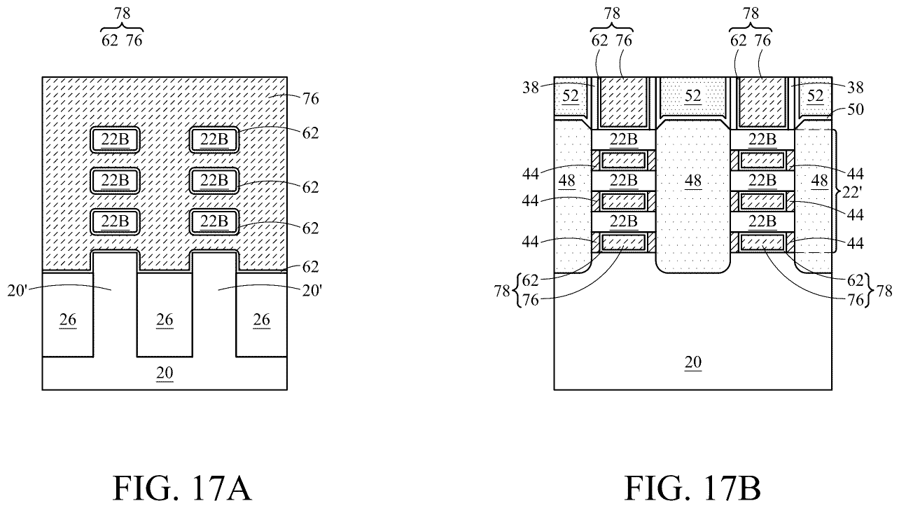

An etching process is thus performed to remove the fluorine-containing layers 70 and diffusion liners 64. The respective process is illustrated as process 238 in the process flow 200 as shown in FIG. 20. In accordance with some embodiments, the etching process may be performed using an etching gas comprising nitrogen fluoride (NF₃) and/or Bifluoride (NH₄HF₂), a wet etching solution comprising HF, or the like. In accordance some alternative embodiments, a carrier gas is added to the etching gas when dry etching is used. The carrier gas may include N₂, Ar, He, or the like. As a result of the etching process, gate dielectrics 62 are revealed again, as shown in FIG. 16. In accordance with alternative embodiments, the fluorine-containing layers 70 is removed, while diffusion liners 64 are not etched, and the subsequently formed work-function layers are deposited over the diffusion liners 64.

In the fluorine drive-in process 72, the fluorine needs to diffuse through diffusion liners 64A and 64B before fluorine can reach gate dielectric layer 62. The thicknesses of diffusion liners 64A and 64B thus affect how much fluorine is diffused into different parts of gate dielectric layer 62, and affects the distribution profile of fluorine in gate dielectric layer 62.

In accordance with some embodiments, due to the formation of disposable interposers 29, the intermixing of silicon and SiGe is reduced because the sacrificial layer 22A is removed before the high-temperature epitaxy process for forming source/drain regions. The corners of nanostructures 22B are thus sharp. The sharp corners of nanostructures 22B cause the difficulty in the filling of the diffusion liners 64A and 64B into the spaces between semiconductor nanostructures 22B. The diffusion liners 64A (or 64B) are thus not necessarily conformal, and the profiles may be adjusted. It is thus possible to adjust process conditions and to adjust the profiles of diffusion liners 64A and 64B, so that the profiles of the fluorine incorporated into different gate dielectrics 62 may be adjusted to optimize the device performance. The sheet end shape of (of nanostructures 22B) can effectively reduce the gate oxide damage caused by the plasma, implantation, or soaking for introducing fluorine.

Referring back to FIG. 15, in accordance with some embodiments, assuming diffusion liners 64A and 64B (collectively referred to as diffusion liners 64) have thickness Tᵢₙₙₑᵣ and thickness Tₒᵤₜₑᵣ. The thickness Tᵢₙₙₑᵣ is the thickness of the inner portions of diffusion liners 64 in the inner parts of the spaces between nanostructures 22B. The thickness Tₒᵤₜₑᵣ is the thickness of the outer portions of diffusion liners 64 outside of (or on the outer side of) the spaces. The thickness Tₒᵤₜₑᵣ may be the thicknesses of the diffusion liners 64 on the sidewalls of nanostructures 22B.

Due to the sharp corners and the small spacing between nanostructures 22B, it is more difficult for the diffusion liners 64 to be formed in the inner portions of the spaces than in places outside of the spaces. Thickness Tᵢₙₙₑᵣ thus has the tendency of being smaller than thickness Tₒᵤₜₑᵣ. When thickness Tᵢₙₙₑᵣ is equal to thickness Tₒᵤₜₑᵣ, the corresponding fluorine amount (such as concentration) diffused to the inner regions (such as regions 74ᵢₙₙₑᵣ) of gate dielectrics 62 is equal to the fluorine amount diffused to the outer regions (such as regions 74ₒᵤₜₑᵣ) of gate dielectrics 62. Conversely, when thickness Tᵢₙₙₑᵣ is smaller than thickness Tₒᵤₜₑᵣ, the corresponding fluorine amount diffused to the inner regions (such as regions 74ᵢₙₙₑᵣ) of gate dielectrics 62 is more than the fluorine amount diffused to the outer regions (such as regions 74ₒᵤₜₑᵣ) of gate dielectrics 62. Accordingly, the profiles of diffusion liners 64A and 64B (FIG. 14) may be adjusted differently to generate different fluorine-incorporation profiles.

In accordance with some example embodiments, diffusion liner 64A is deposited as being more conformal than diffusion liner 64B. For example, referring to FIG. 14, the ratio (T_{inner-A})/(T_{outer-A}), which is also the conformality value of diffusion liner 64A, is greater than the ratio (T_{inner-B})/(T_{outer-B}), which is also the conformality value of diffusion liner 64B. In accordance with some embodiments, the ratio (T_{inner-A})/(T_{outer-A}) may be in the range between about 0.7 and 1.0, and the (T_{inner-B})/(T_{outer-B}) may be in the range between about 0.6 and 0.9. The difference ((T_{inner-A})/(T_{outer-A})−(T_{inner-B})/(T_{outer-B})) may be greater than about 0.05, and may be in the range between about 0.05 and about 0.3.

In accordance with some example embodiments in which the diffusion liners 64A and 64B comprise TiN and are formed using ALD, the profiles of diffusion liners 64A and 64B may be adjusted by increasing or reducing the purging time of the respective precursors. For example, an ALD cycle for forming TiN may include pulsing a titanium-containing precursor such as tetrakis(dimethylamino)titanium (TDMAT), purging the titanium-containing precursor (for example by continuously conducting nitrogen (N₂) or an inert gas such as Ar), pulsing a nitrogen-containing precursor, and purging the nitrogen-containing precursor. The purging of the nitrogen-containing precursor may also be by continuously conducting nitrogen (N₂) or an inert gas such as Ar.

In accordance with some embodiments, to make a diffusion liner 64A to be more conformal, the purging time of both of the titanium-containing precursor and the nitrogen-containing precursor in the formation of the diffusion liner 64A may be increased. Conversely, to make a diffusion liner 64B to be less conformal, the purging time of both of the titanium-containing precursor and the nitrogen-containing precursor in the formation of the diffusion liner 64B may be reduced. To make a diffusion liner 64A to be more conformal, the pulsing durations and dosage pressure for the titanium-containing precursor may be increased. Conversely, to make a diffusion liner 64B to be less conformal, the pulsing durations and dosage pressure for the titanium-containing precursor may be reduced. The pulsing duration and dosage pressure for nitrogen-containing precursor, however, have less, little, or no effect to the conformity, and may be kept unchanged.

In accordance with some embodiments, to make the diffusion liner 64A to be more conformal than diffusion liner 64B, the purging durations T_{purge}A of the titanium-containing precursor and the nitrogen-containing precursor for the ALD of the diffusion liner 64A are greater than the purging durations T_{purge}B of the titanium-containing precursor and the nitrogen-containing precursor for the ALD of the diffusion liner 64B. The ratios T_{purge}A/T_{purge}B may be greater than about 1.2, and may be in the range between about 1.2 and about 80.

In accordance with some embodiments, the pulsing durations TₚᵤₗₛₑA and dosage pressure of the titanium-containing precursor for the ALD of the diffusion liner 64A may be greater than the pulsing durations TₚᵤₗₛₑB and dosage pressure of the titanium-containing precursor for the ALD of the diffusion liner 64B. The ratio TₚᵤₗₛₑA/TₚᵤₗₛₑB may be greater than about 1.2, and may be in the range between about 1.2 and about 5.

As a result of the conformal diffusion liner 64A, in device region 100A, the portions of the gate dielectric 62 in the inner region (refer to regions 74ᵢₙₙₑᵣ in FIG. 15) and the outer regions (refer to regions 74ₒᵤₜₑᵣ in FIG. 15) may have the same fluorine amount and the same fluorine concentrations. In device region 100B, on the other hand, the portions of the gate dielectric 62 in the inner region (refer to regions 74ᵢₙₙₑᵣ in FIG. 15) may have more fluorine amount and higher fluorine concentrations than the portions of the gate dielectric 62 in the outer regions (refer to regions 74ₒᵤₜₑᵣ in FIG. 15). For example, the ratio of the fluorine concentration in the inner region to the fluorine concentration in the outer region may be in the range between about 1.5 and about 20. Accordingly, the fluorine distribution profile in device region 100A is adjusted to be different from the fluorine distribution profile in device region 100B.

In accordance with some embodiments, different surfaces (such as (100) surface and (110) surface of semiconductor) react differently to fluorine, and may have different optimum fluorine concentrations. Since fluorine may also penetrate through gate dielectrics 62 to reach the nanostructures 22B, being able to adjust the fluorine profile enables the adjustment of device performance.

In accordance with some embodiments, to achieve optimum fluorine distribution, with different parts of the nanostructures 22B having different desirable fluorine concentrations, a plurality of sample wafers are manufactured, and sample GAA transistors are formed. All processes for forming the plurality of sample wafers may share the common processes, except the process for depositing the diffusion liners 64. The deposition of the diffusion liners 64 for different sample wafers may use different process conditions such as different purging durations, different pressures, different temperatures, etc.

The resulting profiles of diffusion liners 64 on the plurality of sample wafers may be measured, and the fluorine concentration values in different parts of the nanostructures may be measured. An optimum distribution of fluorine may be selected, and the resulting process conditions for forming the respective diffusion liners may be used for mass production of wafers.

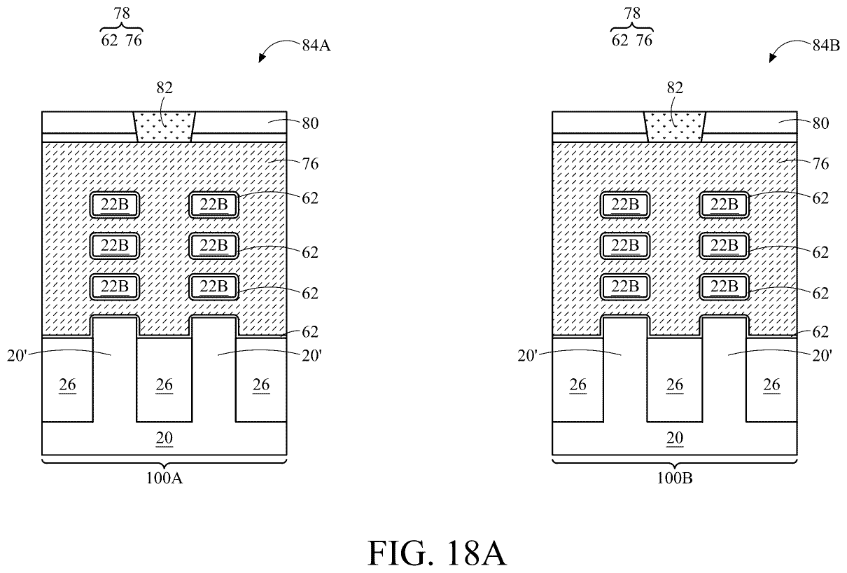

Referring to FIGS. 17A and 17B, gate electrodes 76 are formed to fill the remaining recesses 58. The respective process is illustrated as process 240 in the process flow 200 as shown in FIG. 20. In the formation process, conductive layers are first formed on the high-k dielectric layer, and the remaining portions of recesses 58 are fully filled. Gate electrodes 76 may include a metal-containing material such as TiN, TaN, TiAl, TiAlC, cobalt, ruthenium, aluminum, tungsten, combinations thereof, and/or multilayers thereof. For example, gate electrodes 76 may comprise any number of layers, any number of work function layers, and possibly a filling material. The replacement gate stacks 78 also fill the spaces between adjacent ones of nanostructures 22B, and fill the spaces between the bottom ones of nanostructures 22B and the underlying substrate strips 20′. The gate electrodes 76 may be formed in the device regions 100A and 100B (FIG. 14) in the same formation processes or different processes.

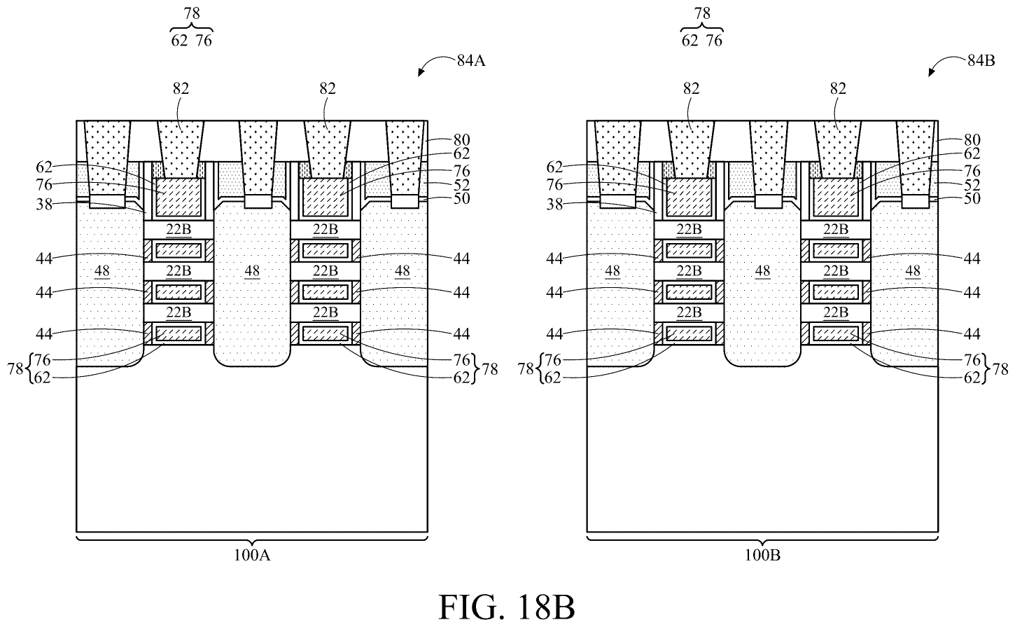

After the filling of recesses 58, a planarization process such as a CMP process or a mechanical grinding process is performed to remove the excess portions of the gate dielectrics 62 and gate electrodes 76. Gate electrodes 76 and gate dielectrics 62 are collectively referred to as gate stacks 78 of the resulting transistors. The resulting structure is shown in FIGS. 18A and 18B.

FIGS. 18A and 18B further illustrate the formation of dielectric layer(s) 80 and gate contact plugs 82 in accordance with some embodiments. Dielectric layers 80 may include an inter-layer dielectric, and may or may not include an etch stop layer between the inter-layer dielectric and the replacement gate stacks 78. Gate contact plugs 82 are formed to electrically connect gate electrodes 76. GAA transistors 84 (including 84A and 84B) are thus formed.

The illustrated GAA transistor 84 may represent the GAA transistor 84 formed in device regions 100A and 100B (FIG. 14), whose formation share common formation processes including the formation of multilayer stacks 22′, disposable interposers 29, gate dielectrics 62, fluorine-containing layers 70, fluorine drive-in processes 72, the formation of fluorine-containing layers 72, and gate electrodes 76. The formation of diffusion liners 64A and 64B, however, are through separate processes.

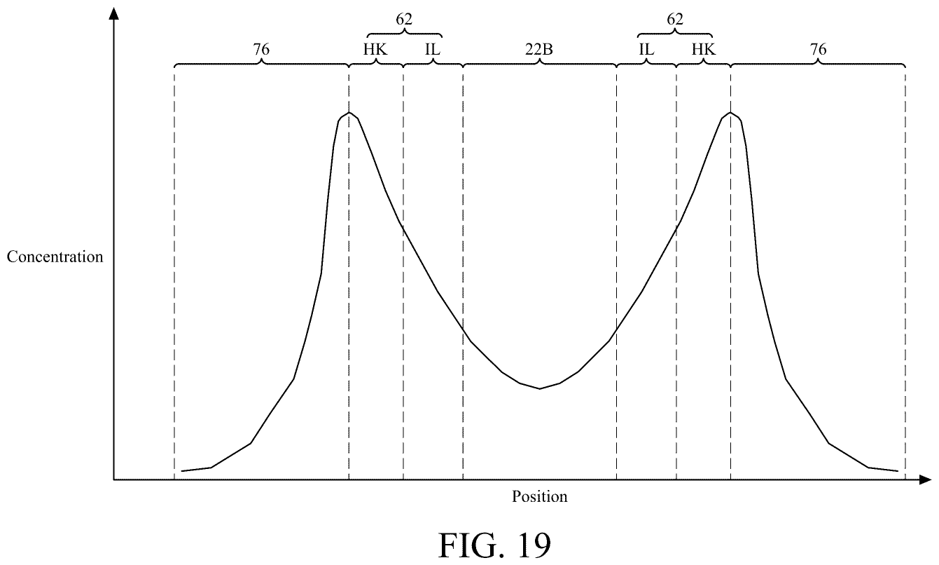

FIG. 19 illustrates a schematic distribution profile of fluorine in the structure shown in FIG. 18B, wherein the distribution profile is along the path 77 that is represented by an arrow in FIG. 18B. The X-axis represents the position in the path 77, and the Y-axis represents the schematic normalized concentration of fluorine. The gate dielectrics 62 may include interfacial layers (IL) and high-k (HK) dielectric layers. In accordance with some embodiments, as shown in FIG. 19, the peak fluorine concentration may occur at the interface between the high-k dielectric layers and gate electrodes 76. Alternatively, the peak fluorine concentration may occur at an intermediate level between the opposing surfaces of the ILs, at the interface between IL and the respective high-k dielectric layer, or may occur at an intermediate level between the opposing surfaces of the HKs. Since the gate electrodes 76 are formed after the removal of the fluorine-containing layers and the diffusion liners, the fluorine concentration has a higher dropping rate, and drops to lower levels, than in the gate dielectrics 62 and the nanostructures 22B.

The embodiments of the present disclosure have some advantageous features. Through the adjustment of the profiles of diffusion liners, the amount/concentration of fluorine in inner regions and outer regions of nanostructure may be controlled to have optimum values. By adjusting the profiles of the diffusion liners, it is also possible to improve the removal of the fluorine-containing layer. This also reduces the damage of gate dielectrics due to the easier removal of the fluorine-containing layer because the removal of the fluorine-containing layer may adopt shorter etching time and/or weaker etching chemicals. Also, by adopting the DOI process, the electrical performance and yield may be significantly improved.

In accordance with some embodiments of the present disclosure, a method comprises removing a first dummy gate stack to form a first trench between first gate spacers; removing a sacrificial layer contacting a first semiconductor region, wherein the sacrificial layer and the first semiconductor region are in the first trench; depositing a first gate dielectric into the first trench and on the first semiconductor region; depositing a first liner on the first gate dielectric; depositing a first fluorine-containing layer over the first liner; performing a drive-in process to drive fluorine in the first fluorine-containing layer into the first gate dielectric; and depositing a first conductive layer over the first gate dielectric.

In an embodiment, the method further comprises, after the drive-in process, removing the first fluorine-containing layer from the first trench. In an embodiment, the method further comprises, after the first fluorine-containing layer is removed, removing the first liner to reveal the first gate dielectric. In an embodiment, the depositing the first liner comprises depositing a metal compound layer. In an embodiment, the depositing the first liner comprises depositing a metal nitride layer. In an embodiment, the removing the sacrificial layer comprises removing a disposable oxide interposer. In an embodiment, the depositing the first conductive layer comprises depositing a work function layer.

In an embodiment, the method further comprises removing a second dummy gate stack to form a second trench between second gate spacers; depositing a second gate dielectric into the second trench and on a second semiconductor region; depositing a second liner on the second gate dielectric, wherein the first liner and the second liner are deposited separately using different process conditions; depositing a second fluorine-containing layer over the second liner, wherein the drive-in process is performed after the second fluorine-containing layer is deposited; and depositing a second conductive layer to fill the second trench.

In an embodiment, the first gate dielectric and the second gate dielectric are deposited in a first common deposition process, and the first fluorine-containing layer and the second fluorine-containing layer are deposited in a second common deposition process. In an embodiment, the first liner and the second liner are deposited using same precursors, and wherein the first liner is deposited using a first atomic layer deposition process comprising first purging processes having first purging durations, and the second liner is deposited using a second atomic layer deposition process comprising second purging processes having second purging durations shorter than the first purging durations.

In an embodiment, the first atomic layer deposition process comprises first pulsing processes having first pulsing durations, and the second atomic layer deposition process comprises second pulsing processes having second pulsing durations equal to or greater than the first pulsing durations. In an embodiment, the drive-in process comprises an annealing process.

In accordance with some embodiments of the present disclosure, a method comprises forming a first plurality of semiconductor nanostructures that are stacked, wherein upper ones of the first plurality of semiconductor nanostructures overlap respective lower ones of the first plurality of semiconductor nanostructures; removing disposable oxide interposers that are between the first plurality of semiconductor nanostructures; depositing a first gate dielectric on the first plurality of semiconductor nanostructures; depositing a first liner on the first gate dielectric, wherein the first liner has a first conformity value; incorporating fluorine into the first liner and the first gate dielectric; removing the first liner to reveal the first gate dielectric; and depositing a work-function layer over the first gate dielectric. In an embodiment, the incorporating fluorine comprises: depositing a fluorine-containing layer over the first liner; performing an anneal process on the fluorine-containing layer; and removing the fluorine-containing layer. In an embodiment, the incorporating fluorine comprises soaking the first liner and the first gate dielectric in a fluorine-containing gas.

In an embodiment, the method further comprises forming a second plurality of semiconductor nanostructures that are stacked, wherein upper ones of the second plurality of semiconductor nanostructures overlap respective lower ones of the second plurality of semiconductor nanostructures; depositing a second gate dielectric on the second plurality of semiconductor nanostructures; depositing a second liner on the second gate dielectric, wherein the second liner comprises a second conformity value lower than the first conformity value; and when the fluorine is incorporated into the first liner and the first gate dielectric, simultaneously incorporating the fluorine into the second liner and the second gate dielectric.

In accordance with some embodiments of the present disclosure, a method comprises depositing a first gate dielectric and a second gate dielectric into a first trench and a second trench, respectively, wherein the first gate dielectric is over a first semiconductor region, and the second gate dielectric is over a second semiconductor region; in a first deposition process, depositing a first liner on the first gate dielectric, wherein the first liner is deposited using a first process condition; in a second deposition process separate from the first deposition process, depositing a second liner on the second gate dielectric, wherein the second liner is deposited using a second process condition different from the first process condition; depositing a fluorine-containing layer comprising a first portion on the first liner and a second portion on the second liner; and performing a drive-in process to drive fluorine in the fluorine-containing layer into the first gate dielectric and the second gate dielectric.

In an embodiment, when the first deposition process is performed, a first hard mask is used to mask the second semiconductor region; and when the second deposition process is performed, a second hard mask is used to mask the first semiconductor region. In an embodiment, the first liner is more conformal than the second liner. In an embodiment, the first liner and the second liner comprise a same material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
removing a first dummy gate stack to form a first trench between first gate spacers;
removing a sacrificial layer contacting a first semiconductor region, wherein the sacrificial layer and the first semiconductor region are in the first trench;
depositing a first gate dielectric into the first trench and on the first semiconductor region;
depositing a first liner on the first gate dielectric;
depositing a first fluorine-containing layer over the first liner;
performing a drive-in process to drive fluorine in the first fluorine-containing layer into the first gate dielectric; and
depositing a first conductive layer over the first gate dielectric.

2. The method of claim 1 further comprising:
after the drive-in process, removing the first fluorine-containing layer from the first trench.

3. The method of claim 2 further comprising:
after the first fluorine-containing layer is removed, removing the first liner to reveal the first gate dielectric.

4. The method of claim 1, wherein the depositing the first liner comprises depositing a metal compound layer.

5. The method of claim 4, wherein the depositing the first liner comprises depositing a metal nitride layer.

6. The method of claim 1, wherein the removing the sacrificial layer comprises removing a disposable oxide interposer.

7. The method of claim 1, wherein the depositing the first conductive layer comprises depositing a work function layer.

8. The method of claim 1 further comprising:
removing a second dummy gate stack to form a second trench between second gate spacers;
depositing a second gate dielectric into the second trench and on a second semiconductor region;
depositing a second liner on the second gate dielectric, wherein the first liner and the second liner are deposited separately using different process conditions;
depositing a second fluorine-containing layer over the second liner, wherein the drive-in process is performed after the second fluorine-containing layer is deposited; and
depositing a second conductive layer to fill the second trench.

9. The method of claim 8, wherein the first gate dielectric and the second gate dielectric are deposited in a first common deposition process, and the first fluorine-containing layer and the second fluorine-containing layer are deposited in a second common deposition process.

10. The method of claim 8, wherein the first liner and the second liner are deposited using same precursors, and wherein the first liner is deposited using a first atomic layer deposition process comprising first purging processes having first purging durations, and the second liner is deposited using a second atomic layer deposition process comprising second purging processes having second purging durations shorter than the first purging durations.

11. The method of claim 10, wherein the first atomic layer deposition process comprises first pulsing processes having first pulsing durations, and the second atomic layer deposition process comprises second pulsing processes having second pulsing durations equal to or greater than the first pulsing durations.

12. The method of claim 1, wherein the drive-in process comprises an annealing process.

13. A method comprising:
forming a first plurality of semiconductor nanostructures that are stacked, wherein upper ones of the first plurality of semiconductor nanostructures overlap respective lower ones of the first plurality of semiconductor nanostructures;
removing disposable oxide interposers that are between the first plurality of semiconductor nanostructures;
depositing a first gate dielectric on the first plurality of semiconductor nanostructures;
depositing a first liner on the first gate dielectric, wherein the first liner has a first conformity value;
incorporating fluorine into the first liner and the first gate dielectric;
removing the first liner to reveal the first gate dielectric; and
depositing a work-function layer over the first gate dielectric.

14. The method of claim 13, wherein the incorporating fluorine comprises:
depositing a fluorine-containing layer over the first liner;
performing an anneal process on the fluorine-containing layer; and
removing the fluorine-containing layer.

15. The method of claim 13, wherein the incorporating fluorine comprises soaking the first liner and the first gate dielectric in a fluorine-containing gas.

16. The method of claim 13 further comprising:
forming a second plurality of semiconductor nanostructures that are stacked, wherein upper ones of the second plurality of semiconductor nanostructures overlap respective lower ones of the second plurality of semiconductor nanostructures;
depositing a second gate dielectric on the second plurality of semiconductor nanostructures;
depositing a second liner on the second gate dielectric, wherein the second liner comprises a second conformity value lower than the first conformity value; and
when the fluorine is incorporated into the first liner and the first gate dielectric, simultaneously incorporating the fluorine into the second liner and the second gate dielectric.

17. A method comprising:
depositing a first gate dielectric and a second gate dielectric into a first trench and a second trench, respectively, wherein the first gate dielectric is over a first semiconductor region, and the second gate dielectric is over a second semiconductor region;
in a first deposition process, depositing a first liner on the first gate dielectric, wherein the first liner is deposited using a first process condition;
in a second deposition process separate from the first deposition process, depositing a second liner on the second gate dielectric, wherein the second liner is deposited using a second process condition different from the first process condition;
depositing a fluorine-containing layer comprising a first portion on the first liner and a second portion on the second liner; and
performing a drive-in process to drive fluorine in the fluorine-containing layer into the first gate dielectric and the second gate dielectric.

18. The method of claim 17, wherein:
when the first deposition process is performed, a first hard mask is used to mask the second semiconductor region; and
when the second deposition process is performed, a second hard mask is used to mask the first semiconductor region.

19. The method of claim 17, wherein the first liner is more conformal than the second liner.

20. The method of claim 17, wherein the first liner and the second liner comprise a same material.
